(19) United States
(12) Patent Application Publication
(10) Pub. No.: US 2007/0122994 A1
(43) Pub. Date: May 31, 2007

(54) NITRIDE SEMICONDUCTOR LIGHT EMITTING ELEMENT

(75) Inventors: Masayuki SONOBE, Kyoto (JP); Norikazu ITO, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Kyoto (JP)

(21) Appl. No.: 11/563,799

(22) Filed: Nov. 28, 2006

(30) Foreign Application Priority Data
Nov. 29, 2005 (JP) 2005-344170

(51) Int. Cl. H01L 33/00; H01L 21/76

(52) U.S. Cl. 438/426; 257/79

(57) ABSTRACT

A nitride semiconductor light-emitting element suppresses leakage currents and non-radiative recombination centers by providing, as an underlying layer of the active layer, a pit formation layer that reliably generates pits, while maintaining a good film quality, so that the internal quantum efficiency is improved, and the light-emitting characteristics are also improved. A nitride semiconductor lamination portion including at least an active layer for forming a light-emitting portion is present on a substrate, and a pit formation layer is formed as a superlattice layer of nitride semiconductor on the side of the substrate of the active layer. The pit formation layer generates pits in the end portions of threading dislocations that are generated in the nitride semiconductor layer on the side of the substrate.

### BACKGROUND OF THE INVENTION

1. Field of the Invention

The present invention relates to a light-emitting element using a nitride semiconductor, and more particularly, the present invention relates to a nitride semiconductor light-emitting element which prevents threading dislocations from extending into an active layer and increasing leakage currents by reliably generating pits underneath the active layer, thus improving brightness.

2. Description of the Related Art

Conventional light-emitting elements using a nitride semiconductor are formed by growing a nitride semiconductor lamination portion that contains a buffer layer and a light-emitting layer formation portion on, for example, a sapphire substrate, etching a portion of this semiconductor lamination portion to expose a conductor formation layer on the lower side of the semiconductor lamination portion, and respectively providing a lower electrode on the exposed surface of the lower-side conductor formation layer and an upper electrode on the upper surface of the semiconductor lamination portion. Meanwhile, in order to avoid complications involving the use of such an insulating substrate, adhesion of contamination caused by etching, or the like, a method is also considered in which a semiconductor substrate formed of SiC is used as the substrate, and a light-emitting portion is formed thereon by laminating a nitride semiconductor.

When a sapphire substrate is used as the substrate, lattice mismatching with the nitride semiconductor layer laminated thereon reaches approximately 14%, so that complete lattice matching cannot be accomplished. Furthermore, even if an SiC substrate is used, there is a high degree of lattice mismatching, so that complete lattice matching cannot be accomplished. Accordingly, an extremely large number of crystal defects are produced in the nitride semiconductor layer that is caused to grow on the substrate, and the crystal defects also extend in the vertical direction through the nitride semiconductor layer that is laminated thereon, so that numerous crystal defects referred to as threading dislocations are present. The density of the threading dislocations becomes 1×10⁸/cm² or more, and when the threading dislocations extend through the active layer, leakage occurs via the threading dislocations, with the threading dislocations acting as non-radiative recombination centers. Therefore, there is a problem in that the emission efficiency (internal quantum efficiency) drops. In order to solve such a problem, a method is considered in which recessed portions called pits are formed in the tip end portions of the threading dislocations in the layer underneath the active layer such that the threading dislocations do not extend into the active layer, thus stopping the threading dislocations, and during the growth of the active layer, these threading dislocations are prevented from extending into the active layer by forming portions of the active layer that extend to the threading dislocations as recessed portions, and subsequently embedding these recessed portions. For example, see Japanese Patent Application Kokai No. 2000-232238.

As described above, in order to form pits, it is necessary to perform etching following the growth of the active layer or to grow a pit generation layer at a low temperature of 800° C. or less. Inserting an etching step during epitaxial growth not only complicates the manufacturing process, but also creates the following problem. Because the element is taken out of a growth furnace and placed into an air atmosphere and then is chemically treated, contamination on the growth surface is generated, which lowers the crystal characteristics of the regrowing gallium nitride-type compound. Furthermore, even in cases where pits are generated as a result of the growth at a low temperature, as is also described in Japanese Patent Application Kokai No. 2000-232238, the following problems are encountered. Specifically, if the growth temperature is too low, the fundamental film quality deteriorates, and if the growth temperature is too high, pits cannot be generated reliably.

### SUMMARY OF THE INVENTION

In order to overcome the problems described above, preferred embodiments of the present invention provide a nitride semiconductor light-emitting element which suppresses and minimizes reactive currents and non-radiative recombination centers by providing, as an underlying layer of the active layer, a pit formation layer that reliably generates pits, while maintaining a good film quality, so that the internal quantum efficiency is improved, and the light-emitting characteristics are also improved.

In addition, preferred embodiments of the present invention provide a nitride semiconductor light-emitting element having a construction that makes it possible to improve the internal quantum efficiency by further preventing leakage currents.

A nitride semiconductor light-emitting element according to a preferred embodiment of the present invention includes a substrate and a nitride semiconductor lamination portion provided on the substrate and at least an active layer for forming a light-emitting portion, wherein a pit formation layer is disposed on the substrate side of the active layer in a superlattice structure of a nitride semiconductor, and the pit formation layer is arranged to generate pits in end portions of threading dislocations that are generated in the nitride semiconductor layer on the side of the substrate.

In this description, nitride semiconductor refers to a compound of Ga, which is a group III element, and N, which is a group V element, or a compound in which a portion or all of Ga, which is a group III element, is substituted by another group III element such as Al or In, and/or a nitride in which a portion of Na, which is a group V element, is substituted by another group V element such as P or As. Furthermore, the term pits refers to recessed portions formed in the end portions of threading dislocations in the shape of a cone or in the shape of a truncated cone, for example.

A nitride semiconductor having a higher band gap energy level than the active layer is embedded inside the recessed portions formed in this active layer continuously with the pits formed in the pit formation layer, so that the injection of electrons and positive holes can be suppressed and minimized without any void portion remaining, which is preferable.

In specific terms, the above-mentioned active layer has a multiquantum well structure including InₓGa₁₋ₓN (0<x≦1) and Al_{y}In_{z}Ga_{1-y-z}N (0≦y<1, 0≦z<1, 0≦y+z<1, and z<x), and the pit formation layer has a superlattice structure including of 10 to 50 pairs of InₐGa₁₋ₐN (0<a≦1) and Al_{b}In_{c}Ga_{1-b-c}N (0≦b<1, 0≦c<1, 0≦b+c<1, c<a<x)

An embedded layer formed from undoped AlᵣGa₁₋ᵣN (0≦r<1) is provided on the active layer on the side opposite from the substrate, and portions of the embedded layer are embedded inside the recessed portions in the active layer, thus making it possible to lower the carrier concentration and to suppress the injection of positive holes. Therefore, this is preferable for suppressing and minimizing leakage currents.

By providing n-type or p-type barrier layers formed from AlₛGa₁₋ₛN (0≦s<1) on the substrate side of the pit formation layer and on the embedded layer on the side opposite from the active layer, it is possible to effectively close in the carrier in the active layer.

With preferred embodiments of the present invention, because the pit formation layer has a superlattice structure, pits can be reliably generated without taking into consideration the reduction of the growth temperature in order to generate pits as a result of the threading dislocations striking the interfaces in the semiconductor layer for forming superlattices. Accordingly, it is not necessary to lower the growth temperature to an extreme extent, and the film quality of the nitride semiconductor layer can be maintained at a favorable level. Furthermore, because a superlattice structure is used, it is possible to maintain the film quality in an even more favorable manner, to reduce the series resistance, and to improve the light-emitting characteristics.

Moreover, because pits are formed in the tip end portions of the threading dislocations before the threading dislocations reach the active layer, the threading dislocations stop and are contained in the pit formation layer without extending into the active layer. Meanwhile, although the recessed portions extend into the active layer after the threading dislocations stop, the recessed portions are filled with the material of the embedded layer or barrier layers, so that the recessed portions do not remain “as is,” and therefore, do not create any problem in terms of reliability. Because such an embedded layer or barrier layers have a higher band gap energy level than the active layer, the injection of electrons and positive holes is much less likely to occur than in the original active layer, so that the current (non-radiative recombination centers) flowing through this region is reduced to an extreme degree and effectively minimized. As a result, it is possible to eliminate the problems of increasing the leakage current and lowering the internal quantum efficiency caused by the threading dislocations directly reaching the active layer, to achieve a reduction in the leakage current and a reduction in non-radiative recombination at the threading dislocations, and to improve the internal quantum efficiency. Accordingly, a nitride semiconductor light-emitting element having a large output can be obtained.

As a result of portions of the undoped embedded layer being embedded inside the recessed portions that are continuous with the pits, it is possible to reduce the carrier concentration, to further reduce reactive currents, and to improve the internal quantum efficiency.

Other features, elements, steps, characteristics and advantages of the present invention will become more apparent from the following detailed description of preferred embodiments thereof with reference to the attached drawings.

### BRIEF DESCRIPTION OF THE DRAWINGS

FIG. 1 is a sectional explanatory diagram of a nitride semiconductor light-emitting element according to a preferred of the present invention.

FIGS. 2(a) and 2(b) show enlarged explanatory diagrams of a pit portion of the construction shown in FIG. 1.

FIG. 3 is a sectional explanatory diagram of another structural example of a nitride semiconductor light-emitting element according to a preferred embodiment of the present invention.

### DETAILED DESCRIPTION OF THE PREFERRED EMBODIMENTS

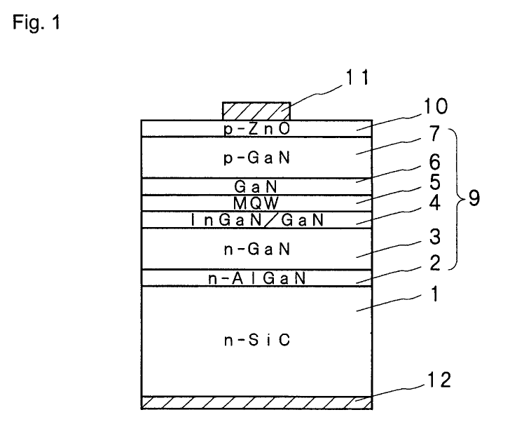

Nitride semiconductor light-emitting elements according to various preferred embodiments of the present invention will be described with reference to the figures. A sectional explanatory diagram of one preferred embodiment of the present invention is shown in FIG. 1. The nitride semiconductor light-emitting element according to the present preferred embodiment of the present invention preferably includes, on a substrate 1, a nitride semiconductor lamination portion including at least an active layer 5 for forming a light-emitting portion, and a pit formation layer 4 disposed on the side of the substrate 1 of the active layer 5 in a superlattice structure of a nitride semiconductor and arranged to generate pits in the end portions of threading dislocations generated in the nitride semiconductor layer on the side of the substrate 1.

In order to suppress a leakage current which occurs as a result of threading dislocations that tend to be generated in the nitride semiconductor layer extending into the active layer for forming the light-emitting portion, the present preferred embodiment of the present invention preferably has a construction that makes it possible to reliably generate pits and to increase the internal quantum efficiency without lowering the film quality even if a layer for generating the pits is inserted, while also adopting a construction in which the pits are formed in the tip end portions of the threading dislocations in the layer underneath the active layer, thus preventing the threading dislocations from extending into the active layer.

As was described above, a method for performing etching after growing an active layer and a method for growing a nitride semiconductor layer at a low temperature have been proposed in order to generate pits. In this method for growing a nitride semiconductor layer at a low temperature, it has been commonly known that if the growth temperature is high, pit generation cannot be reliably accomplished, and that if the growth temperature is low, the film quality of the nitride semiconductor layer drops. When the film quality of the nitride semiconductor layer drops, the carrier cannot be moved smoothly, and series resistance increases, so that the internal quantum efficiency ends up being lowered. Therefore, as a result of repeated diligent studies by the present inventors, the following discovery has been made. If a pit formation layer for generating the pits is formed to have a superlattice structure, the pits can be generated reliably because of increased interfaces, even without lowering the growth temperature of the nitride semiconductor layer very much. Furthermore, it is possible to improve the film quality and to increase the carrier concentration when a superlattice structure is used, compared to a case in which a bulk layer is grown even in the case of growth at the same temperature. Therefore, a pit formation layer 4 having an extremely high film quality and low resistance can be provided.

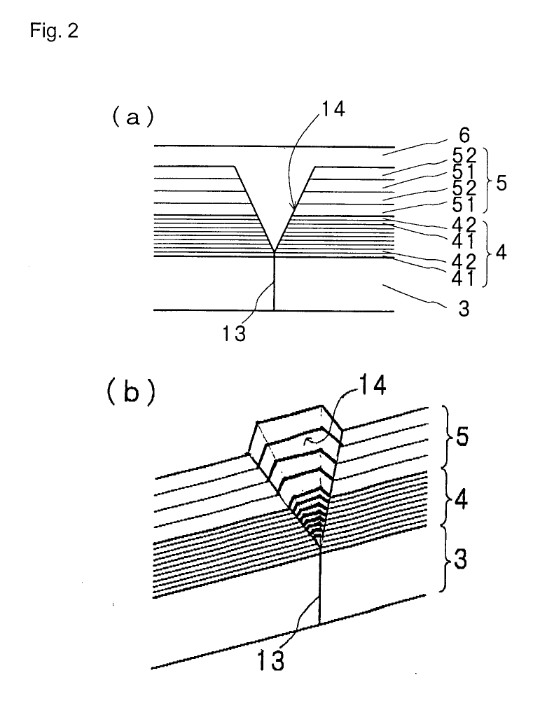

In specific terms, for example, as an enlarged sectional explanatory diagram and a perspective explanatory diagram of a pit portion are shown in FIG. 2, the pit formation layer 4 is formed to have a superlattice structure in which first layers 41 preferably formed of InₐGa₁₋ₐN (0<a≦1, e.g., a=0.05) and having a thickness of, for example, about 0.5 nm to about 10 nm (e.g., about 1 nm) and second layers 42 preferably formed of Al_{b}In_{c}Ga_{1-b-c}N (0≦b<1, 0≦c<1, 0≦b+c<1, c<a, e.g., b=c=0) and having a thickness of, for example, about 0.5 nm to about 10 nm (e.g., about 2 nm) are laminated in approximately 10 to 50 pairs. The pit formation layer 4 may also be formed as an undoped layer, and in the example shown in FIG. 1, this layer may be an n-type layer (the same conductor type as the n-type layer 3 contacted by this pit formation layer 4). Furthermore, either the first layers 41 or second layers 42 may be n-type layers, while the other layers may be undoped layers. Moreover, with regard to the number of pairs to be laminated, if the number is too small, it is difficult to sufficiently separate the pit generating portions and active layer 5, so that a larger number is preferable for improving the film quality. Therefore, it is desirable that this number be as large as possible within the above-mentioned range.

The pit formation layer 4 is a layer for stopping the threading dislocations and forming pits. The formation of the pits is accomplished preferably by growing the nitride semiconductor layer at approximately 600° C. to 850° C. However, the growth of an InGaN-type compound cannot be accomplished unless the temperature is originally set at a low temperature because the decomposition temperature of In is low. Therefore, pits tend to be generated when growing an InGaN-type compound. However, pits can still be generated as a result of the growth at a low temperature even with the use of a GaN or AlGaN-type compound. Because a superlattice structure is formed in preferred embodiments of the present invention, pits can be reliably generated even without lowering the temperature to an extreme extent.

For example, as exaggerated explanatory diagrams are shown in FIG. 2, with regards to pits, the semiconductor layer does not grow in the portions of the threading dislocations 13, and pits are generated in recessed portions 14 formed in a cross-sectional V shape by growing a nitride semiconductor layer at a low temperature of approximately 600° C. to 850° C. as described above. Once pits are formed, as long as the growth is continued at a low temperature, the recessed portions are widened in a V shape and remain as recessed portions. Accordingly, if the active layer 5 is caused to grow continuously, the recessed portions 14 are also continuously formed in the active layer 5 as shown in FIG. 2 because an InGaN-type compound is often used in the active layer 5 and due to the relationship of the band gap energy of an ordinary emission wavelength. For this reason, the growth of the active layer 5 is also caused to occur at a comparably low temperature. The nitride semiconductor layer that grows at a high temperature is embedded in the recessed portions 14 during the growth thereof. Accordingly, this embedding takes place when growing a p-type layer or the like following the growth of the active layer 5. In the present preferred embodiment, however, an embedded layer 6 preferably formed of undoped GaN is caused to grow at a high temperature of about 900° C. to about 1200° C. following the growth of the active layer 5, so that the undoped GaN is embedded at this time.

In preferred embodiments of the present invention, because the layer for generating the recessed portions 14 is formed to have a superlattice structure, pits tend to be generated in the interfaces of the superlattice structure, so that pits can be reliably generated without significantly lowering the growth temperature. Moreover, because the lamination is accomplished using a superlattice structure, the film quality is improved, and in the case of the formation using an n-type layer, the carrier concentration can be increased. Therefore, as will be described later, by making the nitride that is embedded inside the recessed portions 14 using a material with a high band gap energy level and not doping this material, electrons completely avoid the recessed portions, pass through the portions of the pit formation layer 4 where no pits are formed, and are recombined with positive holes in the active layer 5 without any recessed portions 14, so that the light is emitted. Specifically, the nitride semiconductor that is embedded inside the recessed portions 14 has a high band gap, and therefore does not contribute to emission of light, so that it is desirable that the recombination of electrons and positive holes do not occur inside these recessed portions 14. Furthermore, even if a current flows, this current is a reactive current, so that it is better if no current flows. However, in preferred embodiments of the present invention, because a construction is used in which no current tends to flow to the pits (recessed portions 14) even if the carrier concentration is increased with the pit formation layer 4 having a superlattice structure, the current can be utilized extremely effectively.

Substantially the same construction as in the prior art is preferably used except for this pit formation layer 4 and embedded layer 6 (described later). In the example shown in FIG. 1, an SiC substrate is preferably used as the substrate 1. However, a sapphire (Al₂O₃ single crystal) substrate, a semiconductor substrate formed of Si, GaN, or ZnO, or the like may also be used, and the present invention is not limited to this example. In cases where an insulating substrate such as a sapphire substrate is used, as will be described later, in order to connect the electrode that is connected to the underlying layer (n-type layer 3 in the example shown in FIG. 1), a portion of a laminated light-emitting layer formation portion is etched to expose a portion of the n-type layer 3, and an n-side electrode 12 is formed on this exposed surface. A low-temperature buffer layer 2 including, for example, an AlGaN-type compound (a case in which the mixed crystal ratio of Al is 0 is included) is formed to a thickness of about 0.005 μm to about 0.1 μm on the SiC substrate 1, but the composition of the buffer layer 2 is not limited to this example. Furthermore, a semiconductor lamination portion 9 for forming a light-emitting layer is laminated on this buffer layer 2, and a p-side electrode 11 is provided on this surface via a translucent conductive layer 10.

The semiconductor lamination portion 9 has a light-emitting layer formation portion having a double heterojunction structure in which the active layer 5 is formed from a material having a band gap energy level corresponding to the emission wavelength, and barrier layers (n-type layer 3 and p-type layer 7) having a higher band gap energy level than the active layer are provided above and below this active layer 5. In preferred embodiments of the present invention, the pit formation layer 4 is provided on the substrate side of the active layer 5. Furthermore, in the example shown in FIG. 1, the embedded layer 6 preferably formed of, for example, undoped AlᵣGa₁₋ᵣN (0≦r<1, e.g., r=0) is provided on the opposite side of the active layer 5 from the substrate 1, and portions of the embedded layer 6 are embedded inside the pits that are formed in the pit formation layer 4 and the recessed portions 14 in the active layer 5 that are formed continuously with the pits.

In the example shown in FIG. 1, the n-type layer 3 and p-type layer 7 are arranged so as to function as barrier layers in which the carrier is closed into the active layer 5 via an AlₛGa₁₋ₛN (0≦s<1, e.g., s=0) layer, which has a higher band gap energy level than the active layer 5. However, it is not necessary to use such a construction, and it is sufficient as long as the n-type layer and p-type layer are arranged so as to emit light in the active layer. The n-type layer 3 is preferably formed to a thickness of about 1 μm to about 5 μm, and the p-type layer 7 is preferably formed to a thickness of about 0.05 μm to about 5 μm. The n-type layer 3 and p-type layer 7 may be formed of the same composition or of different compositions, and the materials used are not necessarily limited to these materials, either. Moreover, the n-type layer 3 and p-type layer 7 are not limited to a single layer each. For example, it would also be possible to form a GaN layer on the side opposite the active layer 5 to a thickness of about 1 μm to about 3 μm and to achieve a reduction in resistance by means of the GaN layer while increasing the effect of closing in the carrier into the active layer 5. In addition, the entire arrangement may also be formed from AlₛGa₁₋ₛN. Furthermore, in cases where the n-type layer 3 and p-type layer 7 are constructed from multiple layers, the light-emitting layer formation portion is constructed from the layers on the side of the active layer, the active layer 5, and the layers that are respectively provided between these sets of layers.

The formation of an n-type layer can be accomplished by mixing Se, Si, Ge, or Te as an impurity raw material gas of H₂Se, SiH₄, GeH₄TeH₄, or the like into a reactive gas, and the formation of a p-type layer can be accomplished by mixing Mg or Zn as an organic metal gas of cyclopentadienyl magnesium (Cp₂Mg) or dimethyl zinc (DMZn) into a raw material gas. In the case of an n-type layer, however, N tends to evaporate during the film formation even without mixing any impurity, so that an n-type layer can naturally be formed. Therefore, this property can also be utilized.

In the example shown in FIG. 1, the active layer 5 has a multiquantum well (MQW) structure in which well layers preferably formed of, for example, InₓGa₁₋ₓN (0<x≦1 and a<x, e.g., x=0.12) and having a thickness of about 1 nm to about 3 nm and barrier layers preferably formed of, for example, Al_{y}In_{z}Ga_{1-y-z}N (0≦y<1, 0≦z<1, 0≦y+z<1, and z<x, e.g., y=z=0) and having a thickness of about 10 nm to about 20 nm are laminated in 3 to 8 pairs, with this active layer 5 being formed to have a thickness of about 0.05 μm to about 0.3 μm as a whole. The compositions and materials of this active layer 5 are determined by the wavelength of the emitted light. Furthermore, this construction is also not limited to the MQW; a single quantum well structure (SQW) or bulk active layer may also be used.

The embedded layer 6 can be formed to have a thickness of about 0.005 μm to about 0.1 μm from, for example, undoped AlᵣGa₁₋ᵣN (0≦r<1, e.g., r=0). The embedded layer 6 is used so as to be embedded inside the recessed portions 14 that are formed so as to extend from the pit formation layer 4 over to the active layer 5, and as a result of the growth at a high temperature of about 900° C. to about 1200° C., the embedding inside the recessed portions 14 can be accomplished. The embedded layer 6 may have the same composition as the p-type layer 7, or a different composition. However, as the mixed crystal ratio r of Al becomes higher, the embedding effect is greater, and the band gap energy level is higher. Therefore, a higher mixed crystal ratio of Al is preferable from the standpoint of suppressing and minimizing the electron injection into the recessed portions 14. It is preferable that the embedded layer 6 be an undoped layer because the carrier movement can easily be suppressed. However, the electron movement can be suppressed by using a material having a high band gap energy level, so that portions of the p-type layer 7 are embedded inside the recessed portions 14 during the growth of this p-type layer even without providing any embedded layer 6.

The translucent conductive layer 10 including, for example, ZnO, is preferably formed to have a thickness of about 0.1 μm to about 10 μm on the semiconductor lamination portion 9, and the p-side electrode 11 is formed on a portion of this translucent conductive layer 10 with a laminated structure of Ti and Au. The material of this translucent conductive layer 10 is not limited to ZnO; a thin alloy layer of about 2 nm to about 100 nm including ITO or Ni and Au may also be used, as long as the material can cause a current to be diffused over the entire chip while allowing light to pass through. In the case of an Ni—Au layer, because this is a metal layer, if the layer is thick, translucency is lost, so that this layer is thinly formed. In the case of ZnO or ITO, however, light is allowed to pass through, so that a thick layer may be used. In the example shown in FIG. 1, a ZnO layer is preferably formed to have a thickness of approximately 0.3 μm. This translucent conductive layer 10 is provided in order to solve the following problems. Specifically, it is difficult to increase the carrier concentration of a nitride semiconductor layer, especially of a p-type nitride semiconductor layer, to diffuse a current over the entire surface of the chip, and to obtain ohmic contact with the upper electrode 11 which includes a metal film constituting an electrode pad. If these problems are resolved, the translucent conductive layer 10 may also be omitted.

The upper electrode 11 is preferably formed as a p-side electrode because the upper surface of the semiconductor lamination portion is a p-type layer in the example shown in FIG. 1. For instance, the upper electrode 11 is preferably has a laminated structure of Ti/Au, Pd/Au, Ni—Au, or the like so as to have a thickness of about 0.1 μm to about 1 μm as a whole. Furthermore, a lower electrode (n-type electrode) 12 is formed on the back surface of the SiC substrate 1 in a laminated structure of a Ti—Al alloy or Ti/Au so as to have a thickness of about 0.1 μm to about 1 μm as a whole. Moreover, a passivation film (not shown) preferably formed of SiO₂ or the like is preferably provided on the entire surface, excluding the surfaces of the p-type electrode 11 and n-type electrode 12.

Next, a method for manufacturing a nitride semiconductor light-emitting element according to a preferred embodiment of the present invention will be described briefly using a specific example. First, an SiC substrate 1 is set inside an MOCVD (metalorganic chemical vapor deposition) apparatus, for example, and a component gas for a semiconductor layer that grows, i.e., a required gas selected from among, for example, trimethylgallium, trimethylaluminum, (in the case of forming an AlGaN-type layer), trimethylindium, ammonia gas, any of H₂Se, SiH₄, GeH₄, and TeH₄as an n-type dopant gas, and DMZn or Cp₂Mg as a p-type dopant gas, is introduced together with an H₂ gas or N₂ gas used as the carrier gas. An n-type Al_{0.2}Ga_{0.8}N buffer layer 2 and an n-type layer 3 preferably formed of GaN are respectively laminated, for example, at a temperature of about 700° C. to about 1200° C. Then, the substrate temperature is reduced to approximately 760° C., for example, and first layers 41 preferably formed of, for example, In_{0.05}Ga_{0.95}N with a thickness of about 1 nm and second layers 42 preferably formed of, for example, GaN with a thickness of about 2 nm are laminated in approximately 20 pairs, thus forming a pit formation layer 4 having a superlattice structure. In this case, recessed portions 14 are formed in the end portions of threading dislocations 13.

Next, well layers preferably formed of, for example, In_{0.12}Ga_{0.88}N with a thickness of approximately 3 nm and barrier layers preferably formed of GaN with a thickness of approximately 18 nm are laminated in 5 pairs to form an active layer 5 having a multiquantum well (MQW) structure so as to have a thickness of approximately 0.1 μm as a whole. In this case, the recessed portions 14 formed in the pit formation layer 4 are also formed in the active layer 5 as recessed portions that are continuously widened. Afterwards, the substrate temperature is increased to approximately 1065° C., for example, and an embedded layer 6 preferably formed of, for example, GaN is formed into a film having a thickness of approximately 0.02 μm as an undoped layer. Subsequently, a p-type layer 7 preferably formed of, for example, GaN with a thickness of about 0.5 μm to about 2 μm is continuously formed, thus forming a light-emitting layer formation portion by the successive epitaxial growth of the respective layers described above.

Then, an SiO₂ protective film is provided over the entire surface of the semiconductor lamination portion, and annealing is performed at about 400° C. to about 800° C. for approximately 20 to 60 minutes to activate the p-type layer 7. When the annealing is completed, a translucent conductive layer 10 preferably formed of ZnO is formed on the surface of the p-type layer 7 to a thickness of about 0.3 μm by placing a wafer inside a sputtering apparatus or vacuum evaporation apparatus, and a p-side electrode 11 is formed by forming a film of Ti, Al, or the like. Afterwards, the thickness of the SiC substrate 1 is reduced by performing lapping on the back surface side of the SiC substrate 1, and a metal film of Ti, Au, or the like is similarly formed on the back surface of the substrate 1, thus forming a lower electrode 12. Finally, a nitride semiconductor light-emitting element chip is obtained by forming a chip by scribing.

With preferred embodiments of the present invention, because a pit formation layer having a superlattice structure is provided before threading dislocations reach the active layer, pits can be reliably generated in some of the interfaces in the superlattice structure of the pit formation layer without significantly lowering the growth temperature. Accordingly, the threading dislocations are reliably stopped underneath the active layer without extending up to the active layer, and nitride semiconductor having a higher band gap energy level is embedded inside the recessed portions in the active layer, so that a leakage current can be reduced to a great extent. Furthermore, because the pit formation layer for generating pits is formed to have a superlattice structure, the film quality of the semiconductor layer is good, the carrier concentration can be increased, the series resistance can be reduced, and a current can be utilized even more effectively. As a result, the recombination of positive holes and electrons can occur in portions of the active layer where no recessed portions are formed, so that the internal quantum efficiency can be improved considerably with very little wasted current.

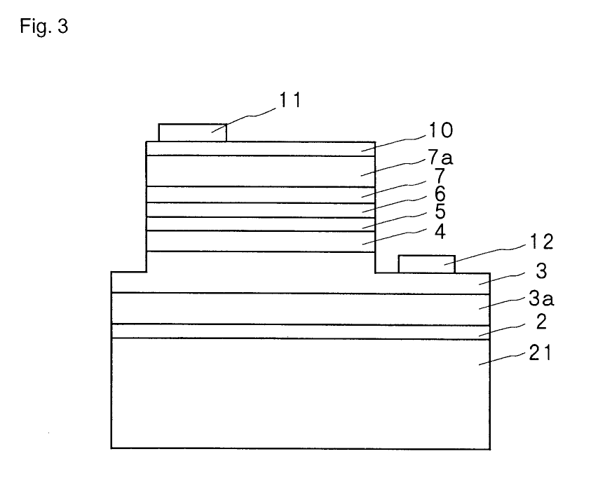

In the above-mentioned example, a conductive SiC substrate is preferably used as the substrate. However, even when a sapphire substrate is used, if a pit formation layer having a superlattice structure is similarly provided on the lower side of the active layer, pits are reliably formed, and at the same time, a pit formation layer preferably formed of a nitride semiconductor layer and having a high film quality can be provided on the lower side of the active layer. The construction of the semiconductor lamination portion may be the same as the above-mentioned laminated structure. In cases where the substrate is formed of sapphire, however, the electrode cannot be taken out from the back surface of the substrate. Therefore, by forming a buffer layer or substrate-side nitride semiconductor layer as an undoped layer, the crystal characteristics can also be improved. Such an example is shown in FIG. 3.

In FIG. 3, a semiconductor layer laminated on a sapphire substrate 21 is constructed by the successive lamination of the following layers: specifically, an AlGaN-type low-temperature buffer layer 2 (the mixed crystal ratio of Al may be 0 or 1) preferably formed of, for example, GaN is formed to a thickness of about 0.005 μm to about 0.1 μm, a high-temperature buffer layer 3a preferably formed of, for example, undoped GaN is then formed to a thickness of about 1 μm to about 3 μm, an n-type layer 3 preferably formed of, for example, Si-doped GaN constituting a barrier layer (a layer having a high band gap energy level) is formed thereon to a thickness of about 1 μm to about 5 μm, a pit formation layer 4 having a superlattice structure of the same construction as described above is laminated, and an active layer 5 having a multiquantum well (MQW) structure is laminated. Furthermore, in the example shown in FIG. 3, an undoped embedded layer 6 preferably formed of, for example, an AlGaN-type compound semiconductor layer is laminated on the surface of the active layer 5, and a p-type layer formed from a p-type barrier layer (layer having a high band gap energy level) 7 and a contact layer 7a preferably formed of, for example, p-type GaN is then laminated, with a total thickness of about 0.2 μm to about 1 μm. In this construction, the buffer layer 2 through the contact layer 7a constitute the semiconductor lamination portion.

Furthermore, the undoped high-temperature buffer layer 3a is used to improve the crystal characteristics of the laminated semiconductor layer of a gallium nitride-type compound, and for this reason, the first layer growing at a high temperature is undoped. Moreover, with regard to the p-type layer 7 and contact layer 7a, the formation of layers containing Al on the side of the active layer 5 is indicated as a preferred example from the standpoint of the effect of closing in the carrier as described above. In addition, because the substrate is an insulator, there is no need to form the buffer layer 2 as a conductive layer, and AlN may also be used.

A translucent conductive layer 10 and a p-side electrode 11 are formed on this semiconductor lamination portion just as in the example described above, and a portion of the laminated semiconductor layer is removed by etching, so that an n-side electrode 12 is formed on the exposed n-type layer 3 by means of a laminated structure preferably formed of, for example, Al, Mo, and Au. The Al layer is laminated with a thickness of about 5 nm to about 20 nm (e.g., about 10 nm), the Mo layer is laminated with a thickness of about 30 nm to about 100 nm (e.g., about 50 nm), and the Au layer is laminated with a thickness of about 0.2 μm to about 1 μm (e.g., about 0.25 μm). A thermal treatment of rapid heating (RTA) is performed for approximately 5 seconds at about 600° C. Although a portion of the Al layer diffuses to the gallium nitride-type compound, the respective metal layers do not form an alloy with each other as a result of the Mo layer acting as a barrier layer, and the Au layer that is not formed into an alloy is secured on the surface of the n-type electrode 12, so that the bonding characteristics of wire bonding can be improved. Furthermore, a passivation film including SiO₂ or the like (not shown) is provided on the entire surface, excluding the surfaces of the p-side electrode 11 and n-side electrode 12.

In the example previously described, the SiC substrate is preferably formed as an n-type layer, and p-type layers are preferably formed toward the surface. This is because the use of this construction is convenient for performing annealing for the purpose of activating the p-type layers. However, it would also be possible to form the substrate and layers that are present on the substrate side of the active layer as p-type layers. Furthermore, the nitride semiconductor is not limited to the above-mentioned examples, and may also be constructed from a nitride material expressed as a general formula of AlₚGa_{q}In_{1-p-q}N (0≦p≦1, 0≦q≦1, and 0≦p+q<1). Moreover, a compound may also be used in which a portion of this N is substituted by another group V element.

Furthermore, the light-emitting layer formation portion is preferably formed to have a double heterojunction structure using a sandwich construction in which the active layer is held between the n-type layer and p-type layer. However, this light-emitting layer may also be constructed similarly by further inserting another semiconductor layer such as a guide layer between any of the layers or using a single heterojunction structure or homo p-n junction structure. In this case, the active layer defines the light-emitting portion.

In addition, the above-mentioned example is an example of LED. In the case of a semiconductor laser, however, the internal quantum efficiency can also be improved by similarly providing a pit formation layer having a superlattice structure on the lower side of the active layer.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A nitride semiconductor light-emitting element comprising:
a substrate; and
a nitride semiconductor lamination portion provided on the substrate, the nitride semiconductor lamination portion including at least an active layer defining a light-emitting portion; wherein
a pit formation layer is disposed on a substrate side of said active layer and is arranged to generate pits in end portions of threading dislocations that are generated in the nitride semiconductor layer on the side of said substrate.

2. The nitride semiconductor light-emitting element according to claim 1, wherein the pit formation layer has a superlattice structure of a nitride semiconductor.

3. The nitride semiconductor light-emitting element according to claim 1, wherein a nitride semiconductor having a higher band gap energy level than said active layer is embedded inside recessed portions formed in the active layer continuously with the pits formed in said pit formation layer.

4. The nitride semiconductor light-emitting element according to claim 1, wherein said active layer has a multiquantum well structure including InₓGa₁₋ₓN (0<x≦1) and Al_{y}In_{z}Ga_{1-y-z}N (0≦y<1, 0≦z<1, 0≦y+z<1, and z<x), and said pit formation layer has a superlattice structure including 10 to 50 pairs of InₐGa₁₋ₐN (0<a≦1) and Al_{b}In_{c}Ga_{1-b-c}N (1≦b<1, 0≦c<1, 0≦b+c<1, c<a<x).

5. The nitride semiconductor light-emitting element according to claim 1, wherein an embedded layer formed from undoped AlᵣGa₁₋ᵣN (0≦r<1) is provided on said active layer on the side opposite from said substrate, and portions of the embedded layer are embedded inside the recessed portions in said active layer.

6. The nitride semiconductor light-emitting element according to claim 5, wherein n-type or p-type barrier layers formed from AlₛGa₁₋ₛN (0≦s<1) are provided on said substrate side of said pit formation layer and on said embedded layer on the side opposite from said active layer.

7. A method of manufacturing a nitride semiconductor light-emitting element comprising the steps of:
providing a substrate;
forming a pit formation layer on the substrate; and
forming a nitride semiconductor lamination portion on the pit formation layer, the nitride semiconductor lamination portion including at least an active layer defining a light-emitting portion; wherein
the pit formation layer is arranged to generate pits in end portions of threading dislocations that are generated in the nitride semiconductor layer on the side of said substrate.

8. The method according to claim 7, wherein the pit formation layer is formed to have a superlattice structure of a nitride semiconductor.

9. The method according to claim 7, further comprising the step of embedding a nitride semiconductor having a higher band gap energy level than said active layer inside recessed portions formed in the active layer continuously with the pits formed in said pit formation layer.

10. The method according to claim 7, wherein said active layer is formed to have a multiquantum well structure including InₓGa₁₋ₓN (0<x≦1) and Al_{y}In_{z}Ga_{1-y-z}N (0≦y<1, 0≦z<1, 0≦y+z<1, and z<x), and said pit formation layer is formed to have a superlattice structure including 10 to 50 pairs of InₐGa₁₋ₐN (0<a≦1) and Al_{b}In_{c}Ga_{1-b-c}N (0≦b<1, 0≦c<1, 0≦b+c<1, c<a<x).

11. The method according to claim 7, further comprising the step of forming an embedded layer from undoped AlᵣGa₁₋ᵣN (0≦r<1) on said active layer on the side opposite from said substrate such that portions of the embedded layer are embedded inside the recessed portions in said active layer.

12. The method according to claim 11, further comprising the step of forming n-type or p-type barrier layers formed from AlₛGa₁₋ₛN (0≦s<1) on said substrate side of said pit formation layer and on said embedded layer on the side opposite from said active layer.
